(19) United States
(12) Patent Application Publication
(10) Pub. No.: US 2017/0270996 A1
(43) Pub. Date: Sep. 21, 2017

(54) SEMICONDUCTOR MEMORY DEIVCE AND ACCESSING METHOD THEREOF

(71) Applicant: Powerchip Technology Corporation, Hsinchu (TW)

(72) Inventor: Atsushi Takasugi, Tokyo (JP)

(73) Assignee: Powerchip Technology Corporation, Hsinchu (TW)

(21) Appl. No.: 15/232,823

(22) Filed: Aug. 10, 2016

(30) Foreign Application Priority Data
Mar. 18, 2016 (JP) 2016-054848

(51) Int. Cl. G11C 11/4093; G11C 11/4096; G11C 11/408

(52) U.S. Cl. CPC G11C 11/4093; G11C 11/4087; G11C 11/4096

(57) ABSTRACT

The semiconductor memory device selectively switches at least two banks based on an input parallel address for writing or reading data, and includes a control unit, which controlled according to a following method: in a first data access, the semiconductor memory device is accessed according to the input parallel address; and then in a second data access and after, the semiconductor memory device is accessed according to a serial address different to the parallel address. Moreover, the semiconductor memory device is constructed by respectively connecting memory cells to intersections of word lines and bit lines, and the serial address contains: a 1^{st} serial address for selecting one word line in the word lines, and a 2^{nd} serial address for selecting one bit line in the bit lines.

### CROSS-REFERENCE TO RELATED APPLICATION

This application claims the priority benefit of Japan application serial no. 2016-054848, filed on Mar. 18, 2016. The entirety of the above-mentioned patent application is hereby incorporated by reference herein and made a part of this specification.

### BACKGROUND OF THE INVENTION

Field of the Invention

The invention relates to a semiconductor memory device such as a dynamic random access memory (DRAM) and an address control method thereof.

Description of Related Art

Along with widespread of the Internet, in an expanded Internet Of Things (IOT) market, demand on the DARAMs with high performance and low cost is increased. In recent years, a double data rate (DDR)-type DRAM is widely used, which has the function of the DDR-type DRAM, and has less number of pins and less number of wirings to decrease a board cost.

### EXISTING TECHNICAL LITERATURES

### Patent Literatures

[Patent literature 1] specification of U.S. Pat. No. 6,597,621

[Patent literature 2] specification of U.S. Pat. No. 5,835,952

[Patent literature 3] specification of U.S. Pat. No. 5,537,577

[Patent literature 4] specification of U.S. Pat. No. 6,310,596

[Patent literature 5] specification of U.S. Pat. No. 4,823,302

[Patent literature 6] specification of U.S. Pat. No. 6,301,649

[Patent literature 7] specification of U.S. Pat. No. 6,920,536

[Patent literature 8] specification of U.S. Pat. No. 5,268,865

[Patent literature 9] specification of U.S. Pat. No. 7,219,200

### PROBLEMS TO BE RESOLVED BY THE INVENTION

However, since the number of pins of the DDR-type DRAM with less pins is decreased, a high-speed performance thereof is inferior to the existing DDR-type DRAM, and the DDR-type DRAM has a problem of inadequate high-speed performance when processing high-quality pixels of a wider frequency band, for example, an animation application of moving picture experts group (MPEG), etc. The above problem is described below.

In recent years, along with widespread of high definition (HD), 2K, 4K liquid crystal display (LCD) televisions (TV), the number of animation pixels is drastically increased. On the other hand, a tolerance of a transmission path used for transmitting the high-quality animation with a high pixel number is limited, so that the technique for compressing and decompressing animation images with a high compression rate becomes very important. The animation compression standard includes MPEG, which is varied into a new standard with a higher compression rate within a period of several years. The MPEG is not limited to home TV, and is widely used in application of playing animation images through the Internet. In the home TV or games, in order to achieve high-quality animation, there is a trend of further speeding a frame rate, so that an operation speed required for MPEG compression has a trend of high speed. Animation images on the Internet start to have 4K animation, so that the MPEG with high compression rate is required. Further, in the market requiring high-speed identification such as vehicle use or factory on-line monitoring, etc., since a camera with a high frame rate of hundreds of frames per second is used, the operation speed required for the MPEG compression is further increased. Namely, the high-speed animation compression operation of MPEG is required in Internet games or animation image transfer, vehicle use, monitoring, factory management, etc., represented by the IOT market.

In order to achieve a high compression rate of MPEG, a mobile detection technique is required. In order to achieve the high-speed compression caused by high mobility detection, it is required to perform a high-speed operation and comparison on differences of random and a small part of pixel elements (block units of pixels) on each of continuous and static images that construct the animation. Previously, in order to achieve high compression of the dynamic images, speciality DRAMs as accessible FIFO or SDRAMs were used. These days, DDR-type DRAM with random high-speed access is adopted (currently, DDR3 is used).

The DDR-type DRAM with less number of pins has been taken as a low-cost DRAM in the IOT market and starts to be applied in a part of the market (for example, a public static image terminal for warehouse management, etc.). However, Since the number of pins of the DDR-type DRAM with less number of pins is cut, the high-speed performance thereof is sacrificed, and a DDR2 with a performance lower than a half of the performance of DDR3 only has a performance of a low-speed version thereof, and can only implement MPEG processing of low resolution and low frame dynamic image. Namely, the DDR-type DRAM with the less number of pins has the problems of unable to perform the MPEG operation of the high compression rate as the processing of high quality animation required in the future IOT market.

FIG. 1A is a schematic diagram of an image of an access control method of a DRAM 100 using a bank interleave technique of an existing example, FIG. 1B is a schematic diagram of a construction example of the DRAM 100, and the construction example of the DRAM 100 represents the access control method of FIG. 1A. In FIG. 1B, the DDR-type DRAM 100 includes:
(1) A memory region of a bank A, and a Y decoder 8 and an X decoder 9 applied thereto;
(2) A memory region of a bank B, and a Y decoder 12 and an X decoder 11 applied thereto. By using a program containing the following steps S1-S6 to bank interleave of the DDR-type DRAM 100, effective access is implemented.

(S1) as shown in FIG. 1A, image data of a 16×16 block 201 on an image 200 is separated into a block 202 containing pixel data of even lines L00-L14 and pixel data of odd lines L01-L15.

(S2) the separated pixel data of the even lines L00-L14 is stored in a block 202A of a specified memory region of the bank A of the DDR-type DRAM 100, and the separated pixel data of the odd lines L01-L15 is stored in a block 202B of a specified memory region of the bank B of the DDR-type DRAM 100.

(S3) line data of the line L00 is accessed as access of a page of the DRAM 100.

(S4) during the step S3, prepare of line data of a next line L01 is completed, and such operation is one of a pipeline function.

(S5) after pixel data of Yi+15 is selected through a selection signal coming from the Y decoder 8 in the line data of the line L100 in the bank A of the DDR-type DRAM 100, pixel data of Yi is immediately accessed through a selection signal coming from the Y decoder 8 in the line data of the line L101 in the bank B.

(S6) pipeline management of the step S4 and the step S5 is repeated to implement seamless block accessing.

FIG. 2 is a front view of an image example of pixel blocks with standard block sizes of MPEG of the existing example. As shown in FIG. 2, generally, the pixel blocks with following three block sizes are used in MPEG.
(1) Small block: block of 8×8 pixels=used in a fast moving situation;
(2) Median block: block of 16×16 pixels;
(3) Large block: block of 32×32 pixels=used in a non-moving or almost non-moving situation.

Moreover, a block of N×N pixels is referred to as N×N block hereinafter.

FIG. 3 is a schematic diagram of a construction example of general colour image data (RGB). In FIG. 3, the general colour image data includes image data of three colours of RGB, and the image data of each colour, for example, has a block unit of 8×8 pixels and each pixel has 8 bits (b0-b7) in a depth direction.

FIG. 4A and FIG. 4B are front views of images of construction examples of a general MPEG block. As shown in FIG. 4A, in order to detect mobility, a 9×9 block, a 17×17 block, a 32×32 block or blocks with larger scales for random block access are required. In FIG. 4A, an address of a center pixel is randomly changed, and a difference between each pixel data and the center pixel data is calculated. Moreover, as shown in FIG. 4B, block access of a checkered-flag pattern is generally used, and in order to detect unsmooth moving in a large region, a pixel skipping method adapted to randomly access the pixel blocks is used.

The patent literature 1 to the patent literature 9 disclose the existing techniques, though in case that the high-speed DDR such as DDR3 or LPFDDR3, etc. cannot be used, a frequency band of the processed image data is limited.

### SUMMARY OF THE INVENTION

The invention is intend to resolve the aforementioned problems, and a following semiconductor memory device and an address control method thereof are provided, i.e. image data of a wider frequency band compared to that of the existing technique such as the MPEG data, etc., can be written into or read from the semiconductor memory device with less number of pins.

### Technical Means for Resolving the Problems

The invention provides a semiconductor memory device, selectively switching at least two banks based on an input parallel address for writing or reading data, where the semiconductor memory device includes:

a control unit, which is controlled according to a following method: in a first data access, accessing the semiconductor memory device according to the input parallel address, and then in a second data access and after, accessing the semiconductor memory device according to a serial address different to the parallel address.

In an embodiment of the invention, the semiconductor memory device is constructed by respectively connecting memory cells to intersections of a plurality of word lines and a plurality of bit lines,

the serial address contains: a 1^{st} serial address for selecting one word line in the plurality of word lines, and a 2^{nd} serial address for selecting one bit line in the plurality of bit lines.

In an embodiment of the invention, the 1^{st} serial address and the 2^{nd} serial address are serially input to the semiconductor memory device.

In an embodiment of the invention, the semiconductor memory device is a semiconductor memory device writing or reading data in block unit,

the control unit is controlled according to a following method: in a first block access, accessing the semiconductor memory device according to the input parallel address; and then in a second block access and after, accessing the semiconductor memory device according to the serial address different to the parallel address.

In an embodiment of the invention, the control unit changes a block size for writing or reading data based on a serial instruction input in a front part of the serial address and representing the block size.

The invention further provides an address control method of a semiconductor device, selectively switching at least two banks based on an input parallel address for writing or reading data, where the address control method of the semiconductor memory device includes:

a control step, implementing control according to a following method: in a first data access, after the semiconductor memory device is accessed according to the input parallel address, and then in a second data access and after, the semiconductor memory device is accessed according to a serial address different to the parallel address.

In an embodiment of the invention, the semiconductor memory device is constructed by respectively connecting memory cells to intersections of a plurality of word lines and a plurality of bit lines,

the serial address contains: a 1^{st} serial address for selecting one word line in the plurality of word lines, and a 2^{nd} serial address for selecting one bit line in the plurality of bit lines.

In an embodiment of the invention, the 1^{st} serial address and the 2^{nd} serial address are serially input to the semiconductor memory device.

In an embodiment of the invention, the semiconductor memory device is a semiconductor memory device writing or reading data in block unit,

the control step implements control according to a following method: in a first block access, accessing the semiconductor memory device according to the input parallel address; and then in a second block access and after, accessing the semiconductor memory device according to a serial address different to the parallel address.

In an embodiment of the invention, in the control step, changing a block size for writing or reading data based on a serial instruction input in a front part of the serial address and representing the block size.

### Effects of the Invention

Therefore, according to the semiconductor memory device and the address control method of the invention, image data of a wider frequency band compared to that of the existing technique such as the MPEG data, etc., can be written into or read from the semiconductor memory device with less number of pins.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic diagram of an image of an access control method of a DRAM using a bank interleave technique of an existing example.

FIG. 1B is a schematic diagram of a construction example of the DRAM, and the construction example of the DRAM represents the access control method of FIG. 1A.

FIG. 2 is a front view of an image example of pixel blocks with standard block sizes of moving picture experts group (MPEG) of the existing example.

FIG. 3 is a schematic diagram of a construction example of general colour image data (RGB).

FIG. 4A is a front view of an image of a construction example of a general MPEG block.

FIG. 4B is a front view of an image of an operation example of a general MPEG block.

FIG. 5A is a block diagram of a construction example of a DDR-type DRAM 100 according to an existing example.

FIG. 5B is a block diagram of a construction example of a DDR-type DRAM 100A of a basic embodiment of the invention.

FIG. 6A is a planar diagram of a pin configuration of a plastic fine pitch ball grid array (FBGA) with 78/96 balls of the DDR2/3-type DRAM of the existing technique.

FIG. 6B is a planar diagram of a pin configuration of a Fine pitch Ball Grid Array or FBGA with 24 balls of the DDR-type DRAM of the existing technique.

FIG. 7 is a graphical timing diagram of address-input read-data-output time sequence used for describing the problem of the DDR-type DRAM 100 with less number of pins of the existing example.

FIG. 8 is a timing diagram of an operation example of the DDR-type DRAM 100 of FIG. 7.

FIG. 9 is a block diagram of a construction example of the DDR-type DRAM of the comparison example.

FIG. 10 is a block diagram of a construction example of a DDR-type DRAM 100A of the embodiment 1.

FIG. 11 is a timing diagram of input output time sequence data used for describing a basic operation of the DDR-type DRAM 100A of FIG. 10.

FIG. 12 is a timing diagram of an operation example of the DDR-type DRAM 100A of FIG. 10.

FIG. 13 is a timing diagram of a variation of FIG. 12.

FIG. 14 is a block diagram of a construction example of a DDR-type DRAM 100B of the embodiment 2.

FIG. 15 is a timing diagram of input output time sequence data used for describing a basic operation of the DDR-type DRAM 100B of FIG. 14.

FIG. 16 is a timing diagram of an operation example of the DDR-type DRAM 100B of FIG. 14.

FIG. 17 is a block diagram of a construction example of a DDR-type DRAM 100C of the embodiment 3.

FIG. 18A is a front view of an image of block size examples used in MPEG coding/decoding in the DDR-type DRAM 100C of the embodiment 3.

FIG. 18B is a front view of an image of block size examples used in MPEG coding/decoding in the DDR-type DRAM 100C of the embodiment 3.

FIG. 18C is a timing diagram of input output time sequence data used for describing a basic operation of the DDR-type DRAM 100C of FIG. 17.

FIG. 19A is a front view of an image of a block access operation of an 8×8 block unit in the DDR-type DARAM 100C of FIG. 17.

FIG. 19B is a block diagram of a block access operation of an 8×8 block unit in the DDR-type DARAM 100C of FIG. 17.

FIG. 20 is a timing diagram of an operation example of the DDR-type DRAM 100C of FIG. 17.

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

Abstract of implementations compared with the existing example.

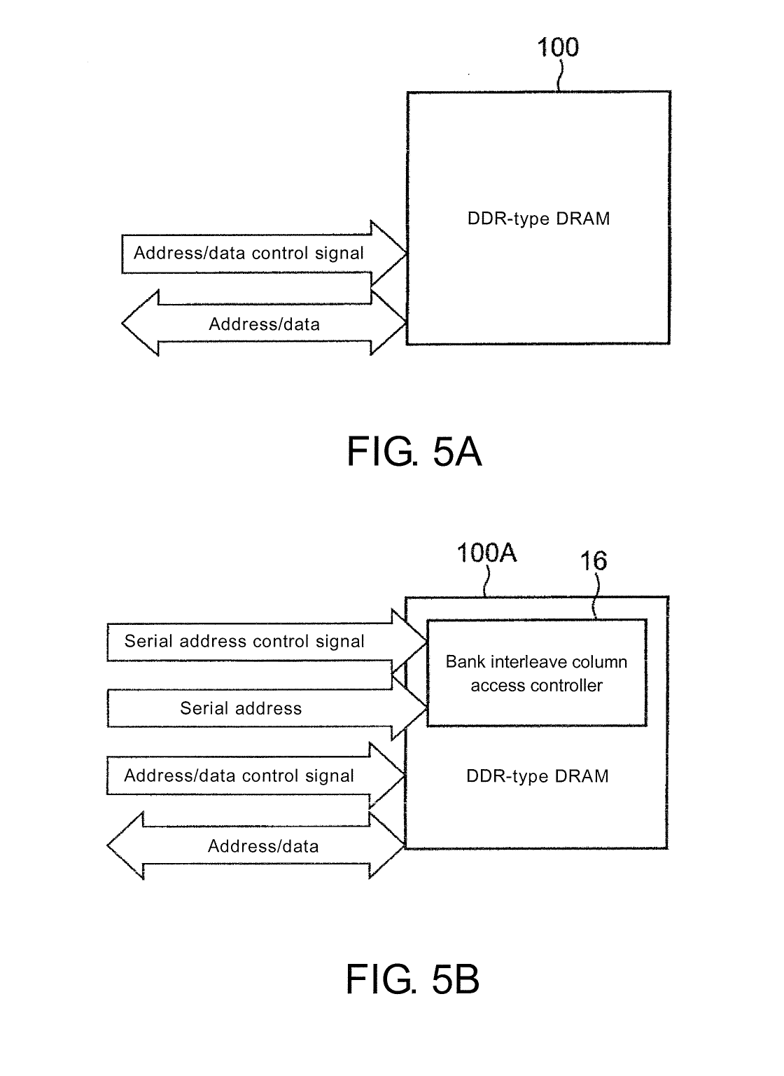

FIG. 5A is a block diagram of a construction example of a DDR-type DRAM 100 according to an existing example, FIG. 5B is a block diagram of a construction example of a DDR-type DRAM 100A of a basic embodiment of the invention. In FIG. 5A, the DDR-type DRAM 100 uses an address/data control signal to input an address or data, or read data from the DRAM. Comparatively, the DDR-type DRAM 100A of FIG. 5B is characterized in that besides using the address/data control signal, a serial address control signal and a serial address are input to a bank interleave column access controller 16 of embodiment 1, so as to input the address or data, or read data from the DRAM. Namely, even the DRAM 100A with less number of pins may implement bank interleave access (which is referred to alternatively access banks A and B by using column line data) by using the input serial address control signal and the serial address. Moreover, access of each block can be performed based on a block access controller 17 and a block access controller 19 of an embodiment 2 and an embodiment 3, which is described in detail later.

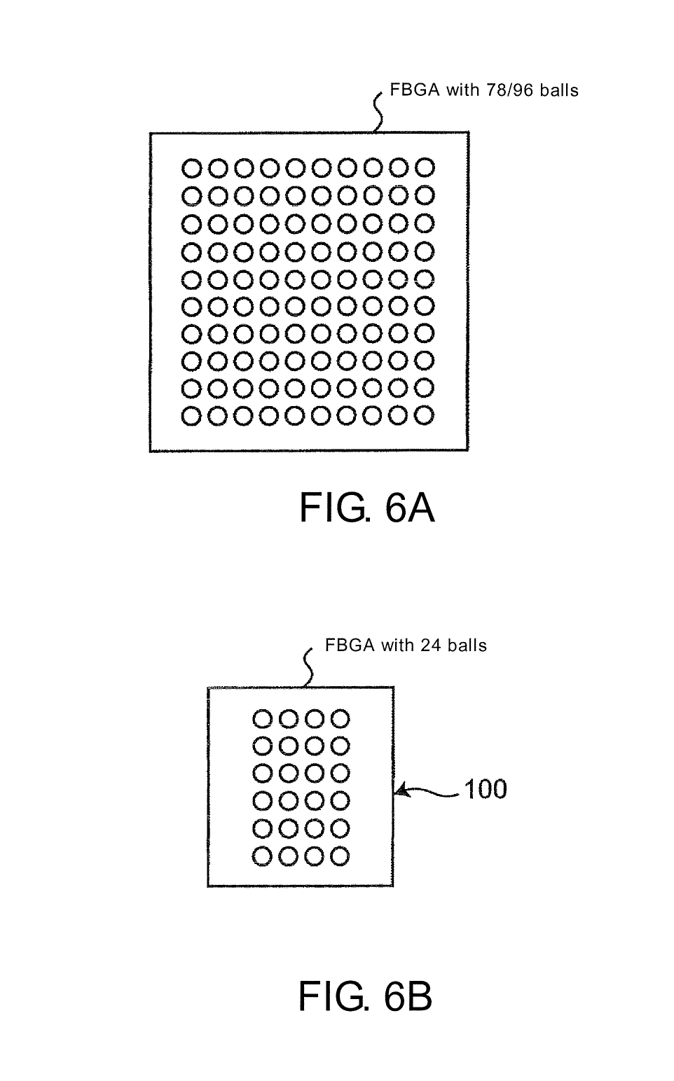

FIG. 6A is a planar diagram of a pin configuration of a plastic fine pitch ball grid array (FBGA) with 78/96 balls of the DDR2/3-type DRAM of the existing technique, and FIG. 6B is a planar diagram of a pin configuration of a FBGA with 24 balls of the DDR-type DRAM of the existing technique. Although the DDR-type DRAM of FIG. 6A has high chip cost and high system cost, it can be applied to wide band application. Comparatively, in the DDR-type DRAM of FIG. 6B, 12 pins of the 24 pins are used for the control signal, and although the DDR-type DRAM of FIG. 6B has lower chip cost and lower system cost, it cannot be applied to the wide band application. Namely, although the DDR-type DRAM with less number of pins can be applied in some applications, it has a problem of unable to achieve adequate frequency band due to a pin arrangement of less number of pins.

The embodiment of the invention is intend to provide a semiconductor memory device capable of inputting outputting image data with wider frequency band compared to that of the existing technique in the DDR-type DRAM with less number of pins. In the present embodiment, to be specific, the package of FBGA with 24 balls of FIG. 6B is adopted in order to accommodate the DDR-type DRAM with less number of pins. Moreover, regarding a transfer speed, 333 Mbps/DQ is, for example, taken as a target value to implement high performance below 50% in random access.

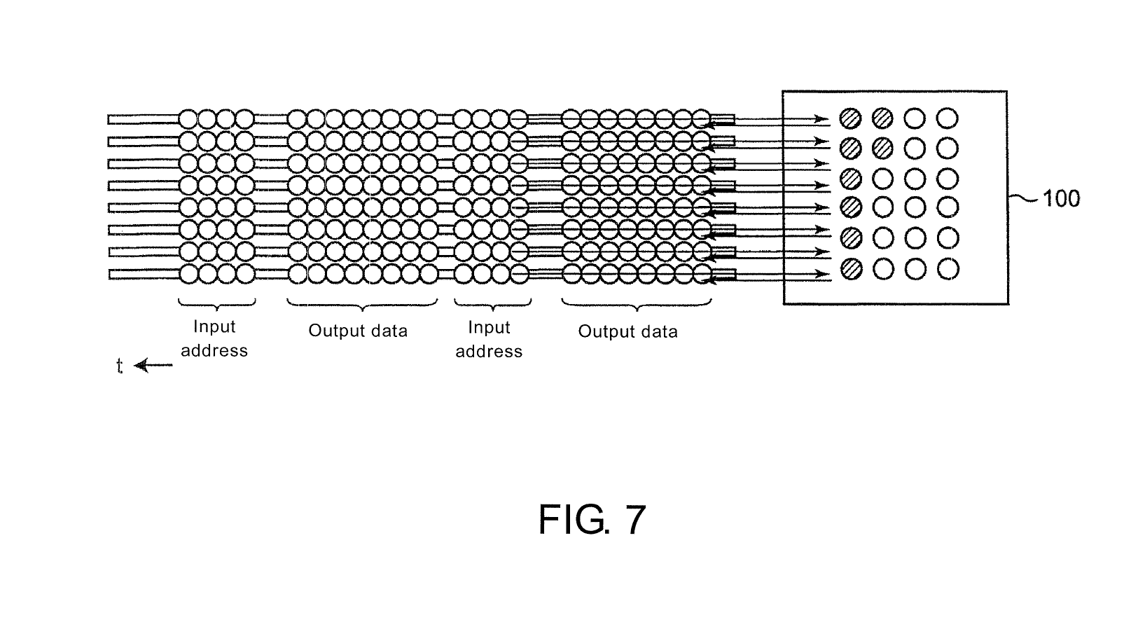

FIG. 7 is a graphical timing diagram of address input read data output time sequence used for describing the problem of the DDR-type DRAM 100 with less number of pins of the existing example. In FIG. 7, 8 pins in the 24 pins of the DDR-type DRAM 100 are taken as data input output pins (shadow lines in FIG. 7). As shown in FIG. 7, in the DDR-type DRAM of the existing example, when the input address is input, the data stored in the corresponding address is sequentially output. However, when address is input to the data input output pins, access of the DRAM is temporarily suspended, which interferes a random block access to greatly decrease an access speed, and the frequency band of data is greatly decreased.

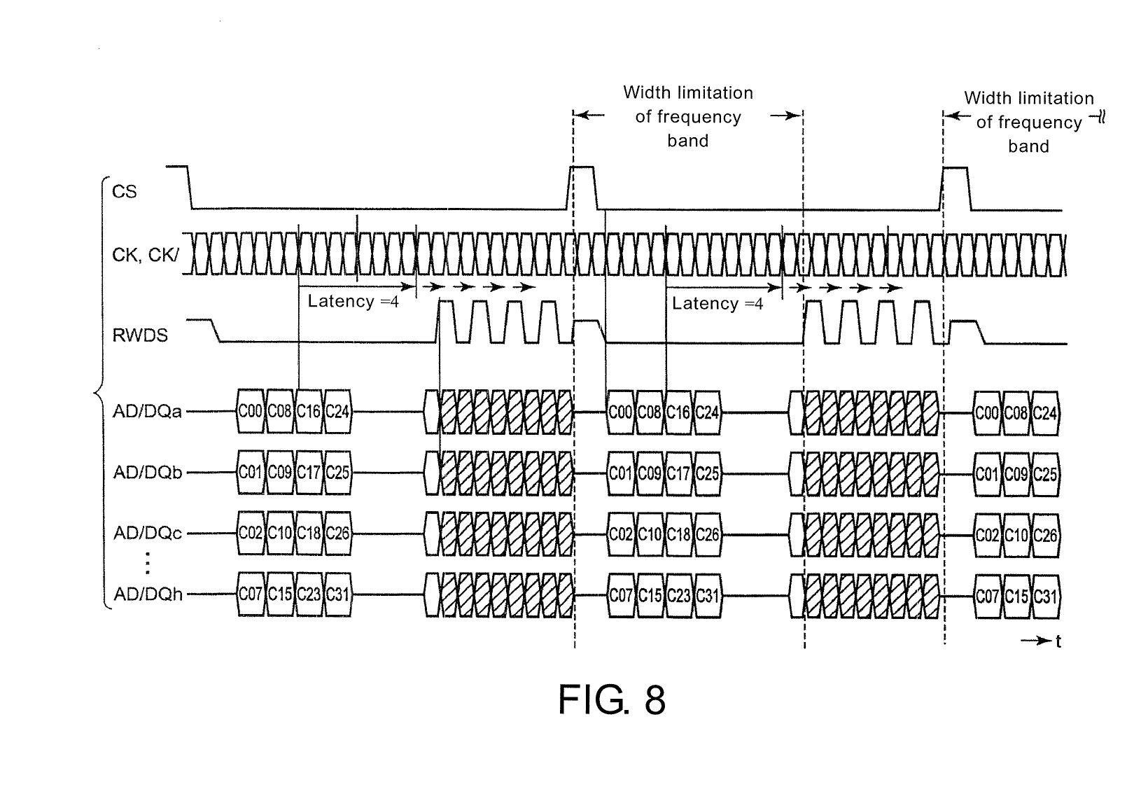

FIG. 8 is a timing diagram of an operation example of the DDR-type DRAM 100 of FIG. 7. Following signals are indicated in FIG. 8:
(1) CS: chip selection signal;
(2) CK, CK/: clock;
(3) RWDS: read write data strobe signal;
(4) AD/DQa-AD/DQh: address or data of 8 bits (input output through an address/instruction buffer 3 and a data buffer 4).

As shown in FIG. 8, similar to the MPEG application, if the number of serial access bits is decreased, the frequency band of the input output data is below a half due to latency and the address/data pins.

### COMPARISON EXAMPLE

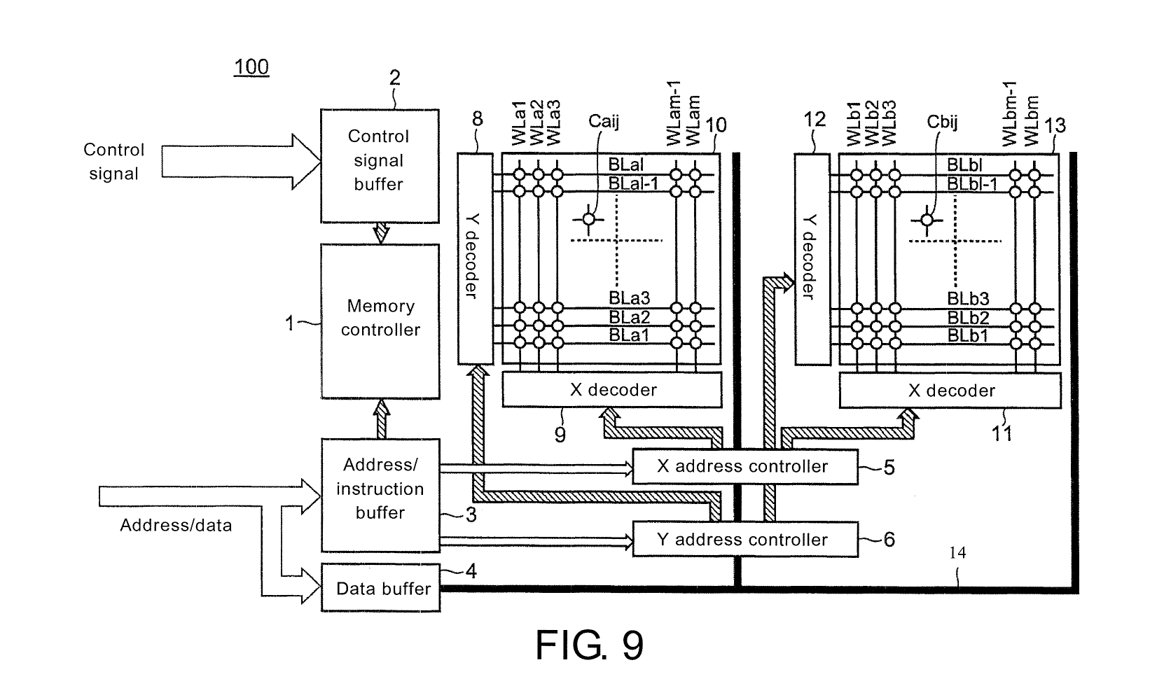

FIG. 9 is a block diagram of a construction example of the DDR-type DRAM 100 of the comparison example. In FIG. 9, the DDR-type DRAM 100 is composed of a memory controller 1, a control signal buffer 2, an address/instruction buffer 3, a data buffer 4, an X address controller 5, a Y address controller 6, a Y decoder 8 for the bank A, an X decoder 9 for the bank A, a memory array 10 of the bank A, an X decoder 11 for the bank B, a Y decoder 12 for the bank B, a memory array 13, a data bus 14 and a serial address buffer 15. The memory array 10 includes memory cells Caij at intersections between word lines WLa1-WLam and bit lines BLa1-BLa1, and the memory array 13 includes memory cells Cbij at intersections between word lines WLb1-WLbm and bit lines BLb1-BLb1. The DDR-type DRAM 100 is a DRAM with less number of pins accommodated in the package of the FBGA with 24 balls, which uses common terminals of the same 8 pins to input output address and data.

In FIG. 9, the X decoder 9 and the Y decoder 8 are respectively configured in order to select the word lines WLa1-WLam and the bit lines BLa1-BLa1 of the memory array 10 of the bank A. Moreover, the X decoder 11 and the Y decoder 12 are respectively configured in order to select the word lines WLb1-WLbm and the bit lines BLb1-BLb1 of the memory array 13 of the bank B. A control signal used for controlling an operation of the DDR-type DRAM 100 is input to the memory controller 1 through the control signal buffer 2. On the other hand, an address and instruction (parallel) are inputted to the X address controller 5 and the Y address controller 6 through the address/instruction buffer 3. The X address controller 5 outputs an X address to the X decoder 9 and the X decoder 11 to select a word line of each of the memory array 10 and the memory array 13 of the bank A and the bank B. Moreover, the Y address controller 6 outputs a Y address to the Y decoder 8 and the Y decoder 12 to select a bit line of each of the memory array 10 and the memory array 13 of the bank A and the bank B. Then, the address/instruction buffer 3 outputs the instruction to the memory controller 1. The parallel data to be written is input and written to the memory array 10 and the memory array 13 of the bank A and the bank B through the data buffer 4. On the other hand, the data read from the memory array 10 and the memory array 13 of the bank A and the bank B is output through the data buffer 4. The memory controller 1 performs sequence control for data write, delete and read operations to the memory array 10 and the memory array 13 of the bank A and the bank B.

### Embodiment 1

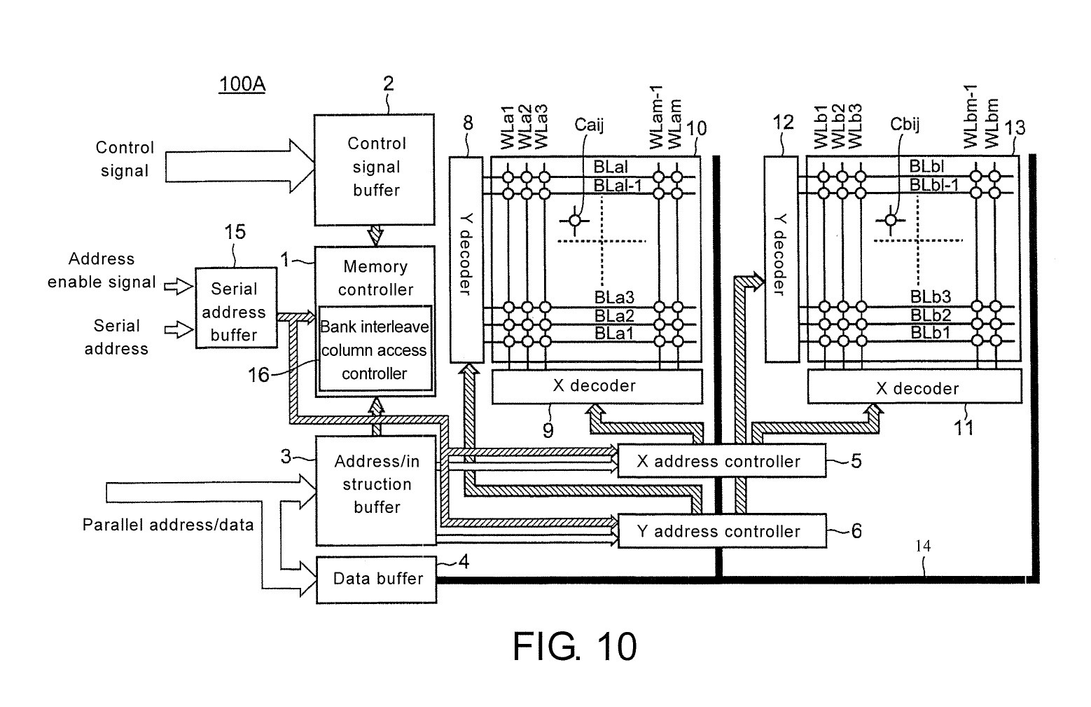

FIG. 10 is a block diagram of a construction of a DDR-type DRAM 100A of the embodiment 1. In FIG. 10, compared to the DDR-type DRAM 100 of the comparison example of FIG. 9, the DDR-type DRAM 100A of the embodiment 1 has a serial address buffer 15, and the memory controller 1 has a bank interleave column access controller 16.

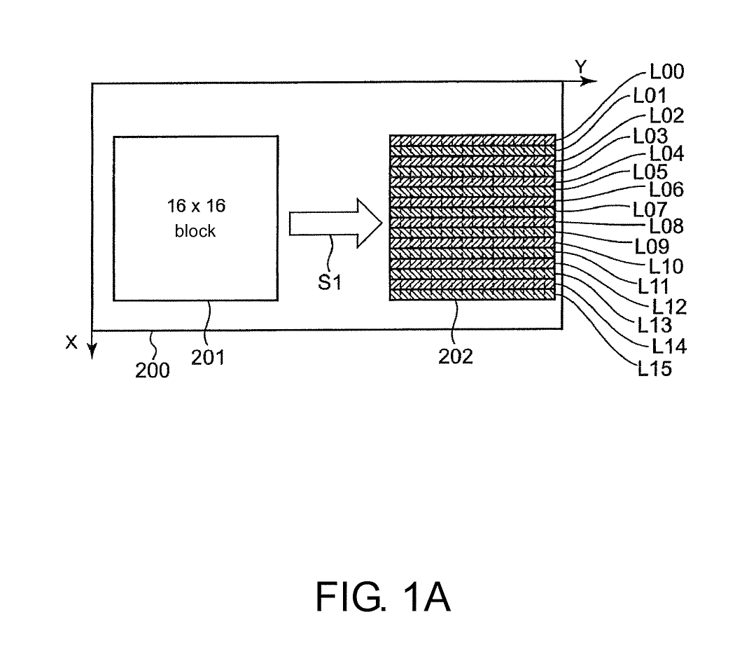

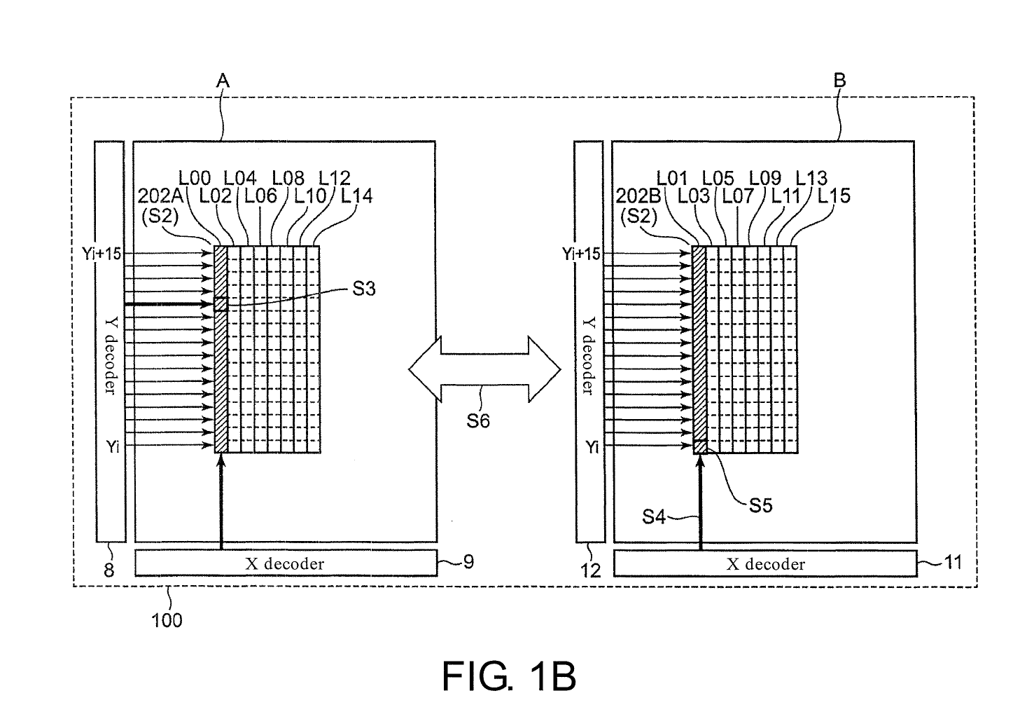

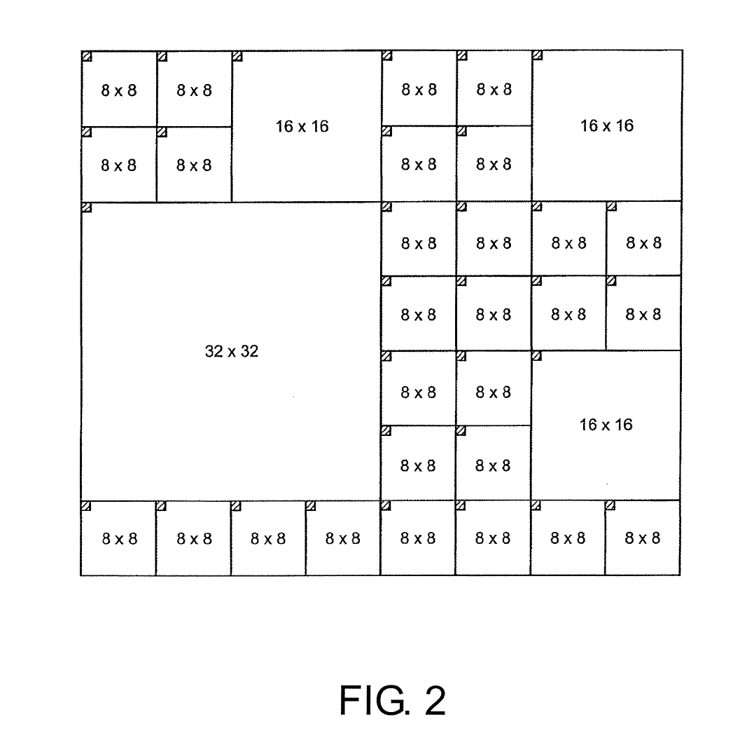

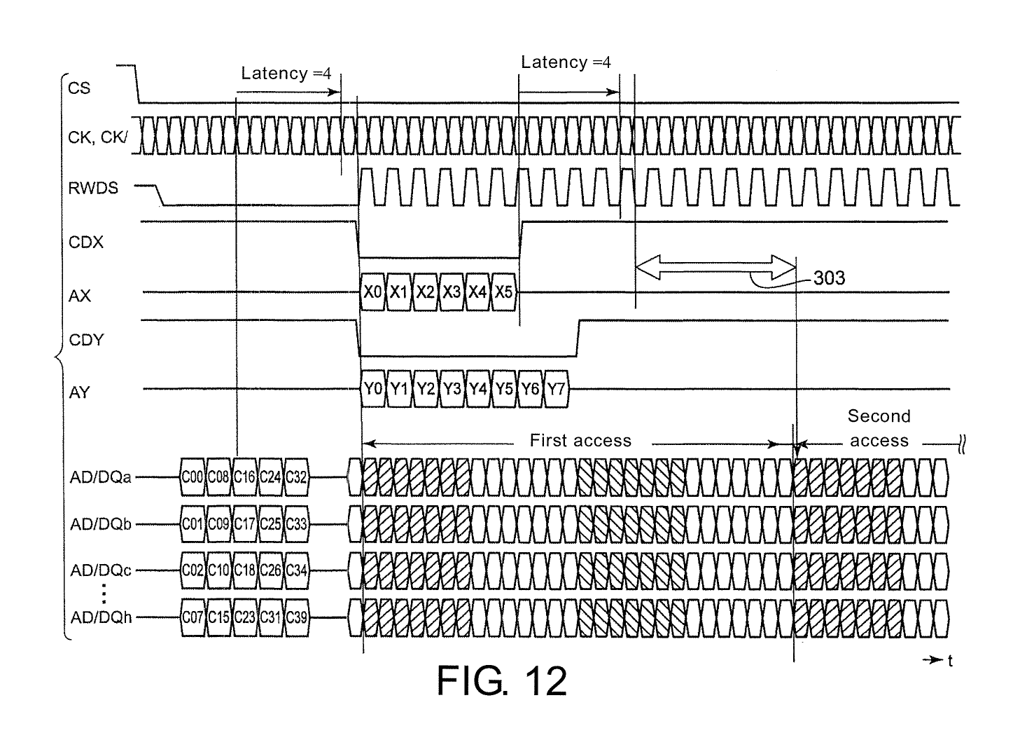

In FIG. 10, the serial address buffer 15 inputs and temporarily stores access related addresses, etc. of a second block and after, i.e. a serial X address AX, a serial X address enable signal CDX, a serial Y address AY, and a serial Y address enable signal CDY (referring to FIG. 12). The serial X address enable signal CDX and the serial Y address enable signal CDY are output to the bank interleave column access controller 16, and the serial X address AX and the serial Y address AY are respectively output to the X address controller 5 and the Y address controller 6. The X address controller 5 and the Y address controller 6 use the addresses coming from the address/instruction buffer 3 in access of a first block, and use the serial addresses coming from the serial address buffer 15 to implement address designation in access of the second block and after. The bank interleave column access controller 16 accesses a column of a designated initial address in a bank interleave manner (as shown in FIG. 1A and FIG. 1B, the bank A and the bank B are alternated) based on the input address and the serial address, so as to perform sequence control for data write, delete and read operations.

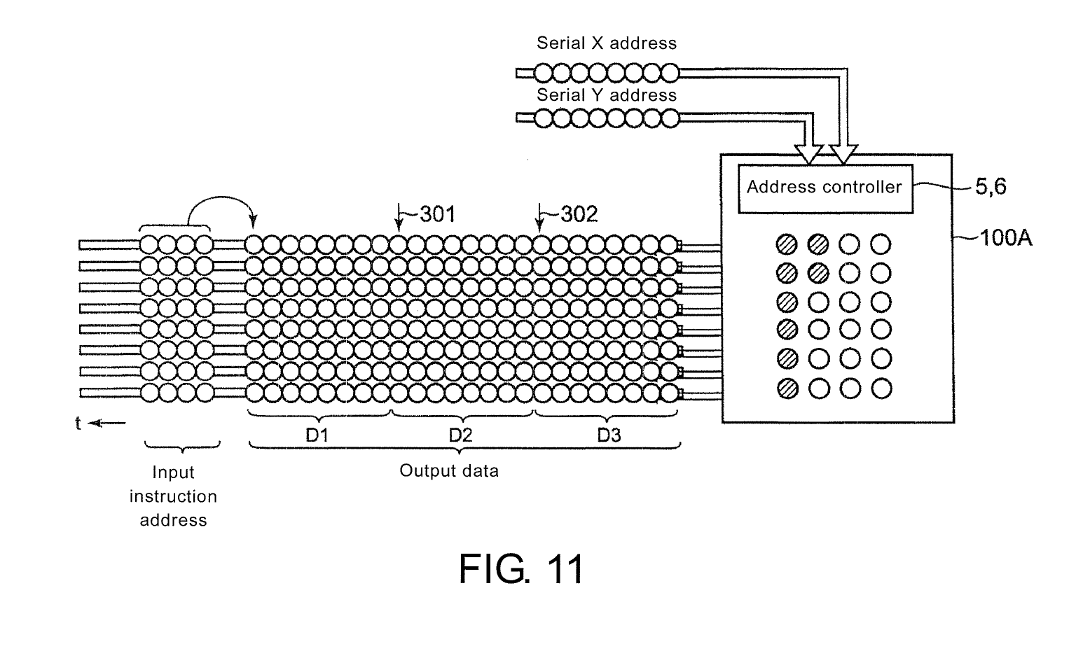

FIG. 11 is a timing diagram of input output time sequence data used for describing a basic operation of the DDR-type DRAM 100A of FIG. 10. In FIG. 11, in access of the first block, data D1 is read based on the initial address of the address/instruction buffer 3, and in access of the second block and after, data D2, data D3, . . . (301 and 302 of FIG. 11) are read based on the serial X address and the serial Y address of the serial address buffer 15. Therefore, the serial address buffer 15 and the bank interleave column access controller 16 may implement hidden address input of pipelines. According to such method, in access of the second block and after, the output data D2, the output data D3, . . . , can be read without interruption, and the writing operation is the same.

FIG. 12 is a timing diagram of an operation example of the DDR-type DRAM 100A of FIG. 10, and following signals are indicated in FIG. 12:
(1) CS: chip selection signal;
(2) CK, CK/: clock;
(3) RWDS: read write data strobe signal;
(4) CDX: serial X address enable signal;
(5) AX: serial X address;
(6) CDY: serial Y address enable signal;
(7) AY: serial Y address;
(8) AD/DQa-AD/DQh: address or data of 8 bits (input output through the address/instruction buffer 3 and the data buffer 4).

According to FIG. 12, it is known that in access of the first block, the address is designated by using the address coming from the address/instruction buffer 3, and in access of the second block and after, the address is designated by using the serial address coming from the serial address buffer 15 to output data. Moreover, in FIG. 12, by configuring a sufficient tolerance period 303 of RAS latency, the serial address AX and the serial address AY are input during the specified period, and data of the corresponding addresses is output through a sufficient period. For example, sufficient operation is implemented in block access of the MPEG application.

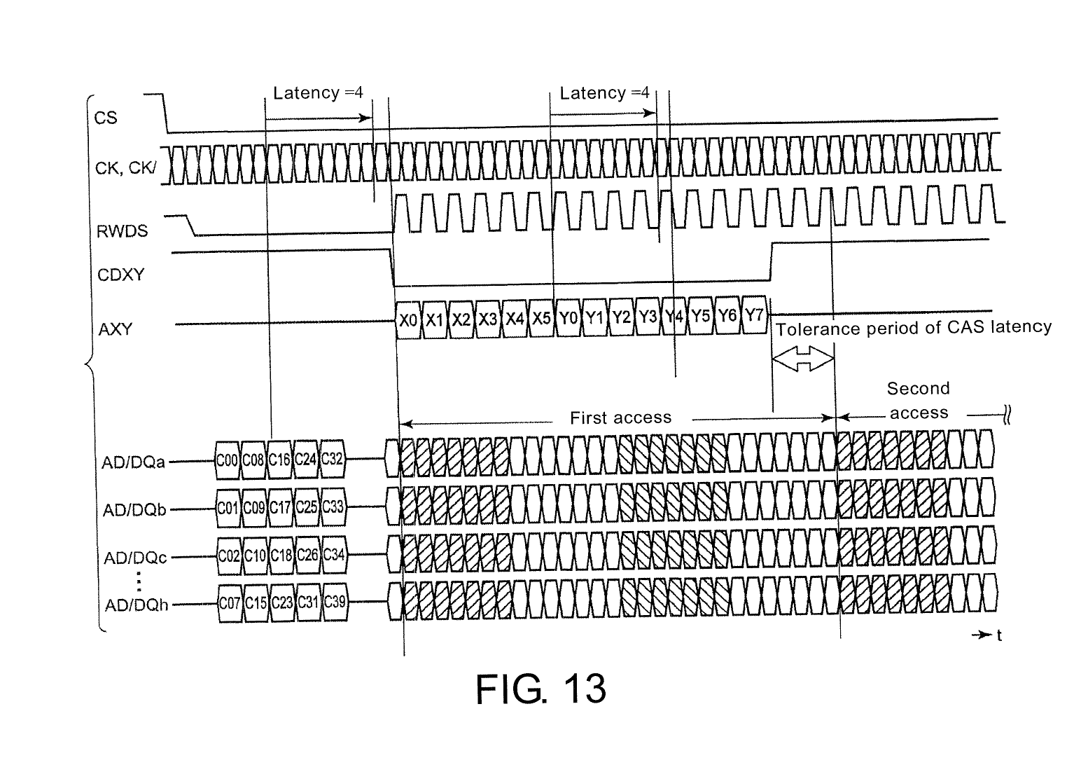

FIG. 13 is a timing diagram of a variation of FIG. 12. Compared to the embodiment 1 of FIG. 12, the variation of FIG. 13 has following differences.
(1) A serial address enable signal CDXY is composed of a serial X address enable signal CDX and a serial Y address enable signal CDY.
(2) A serial address AXY is composed of a serial X address AX and a serial Y address AY.

According to FIG. 13, it is known that the sufficient tolerance period 304 of the RAS latency is shorter than the tolerance period 303 of FIG. 12, though the operation of block access of the MPEG application can still be implemented.

### Embodiment 2

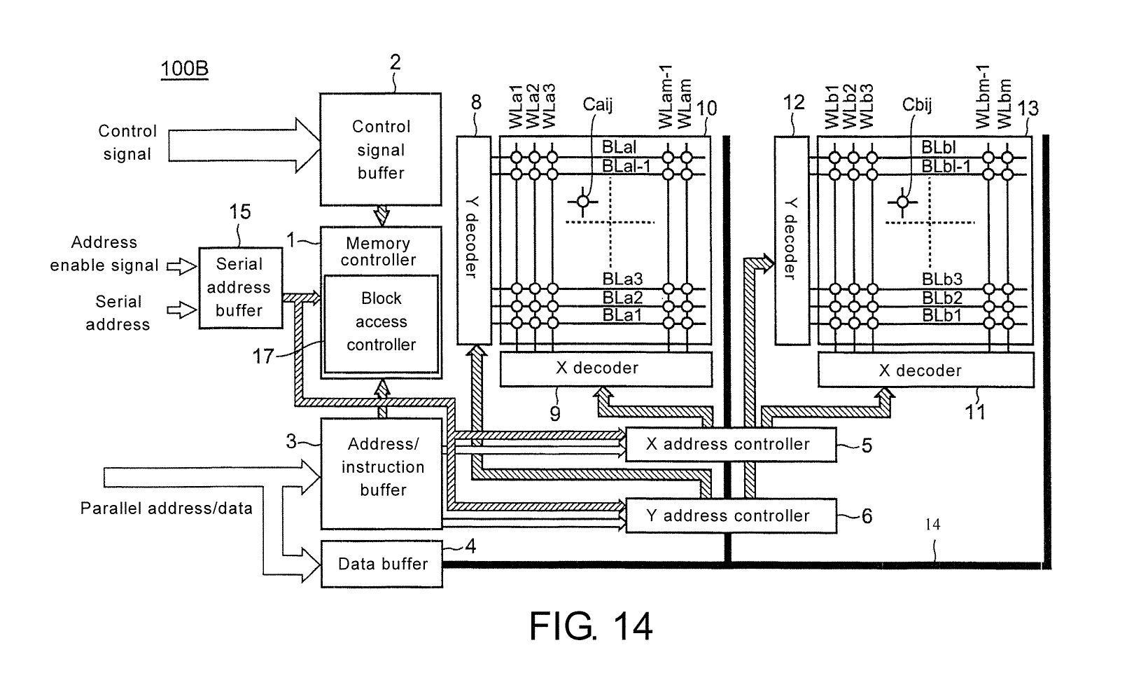

FIG. 14 is a block diagram of a construction of a DDR-type DRAM 100B of the embodiment 2. In FIG. 14, compared to the DDR-type DRAM 100 of the comparison example of FIG. 9, the DDR-type DRAM 100B of the embodiment 2 has a serial address buffer 15, and the memory controller 1 has a block access controller 17.

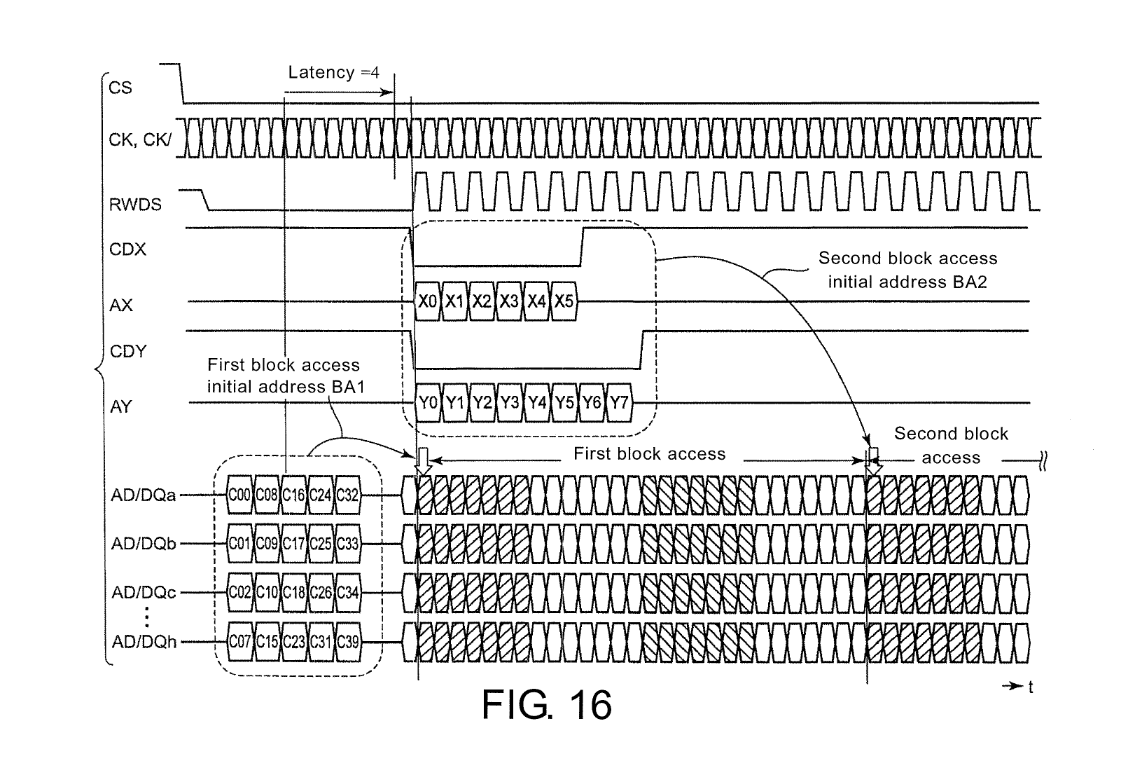

In FIG. 14, the serial address buffer 15 inputs and temporarily stores access related addresses, etc. of the second block and after, i.e. a serial X address AX, a serial X address enable signal CDX, a serial Y address AY, and a serial Y address enable signal CDY (referring to FIG. 16). The serial X address enable signal CDX and the serial Y address enable signal CDY are output to the block access controller 17, and the serial X address AX and the serial Y address AY are respectively output to the X address controller 5 and the Y address controller 6. The X address controller 5 and the Y address controller 6 use an initial address BA1 coming from the address/instruction buffer 3 in access of the first block, and use the serial address coming from the serial address buffer 15, i.e. an initial address BA2 to implement address designation in access of the second block and after. The block access controller 17 performs block access to the designated initial address in the bank interleave manner (as shown in FIG. 1A and FIG. 1B, the bank A and the bank B are alternated) based on the input address and the serial address, so as to perform sequence control for data write, delete and read operations.

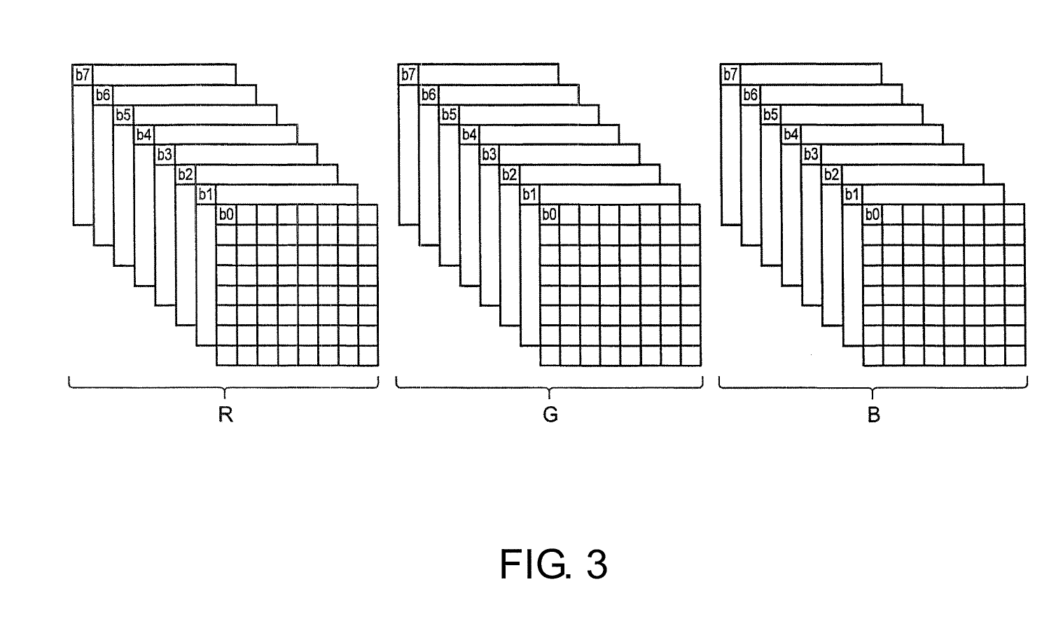

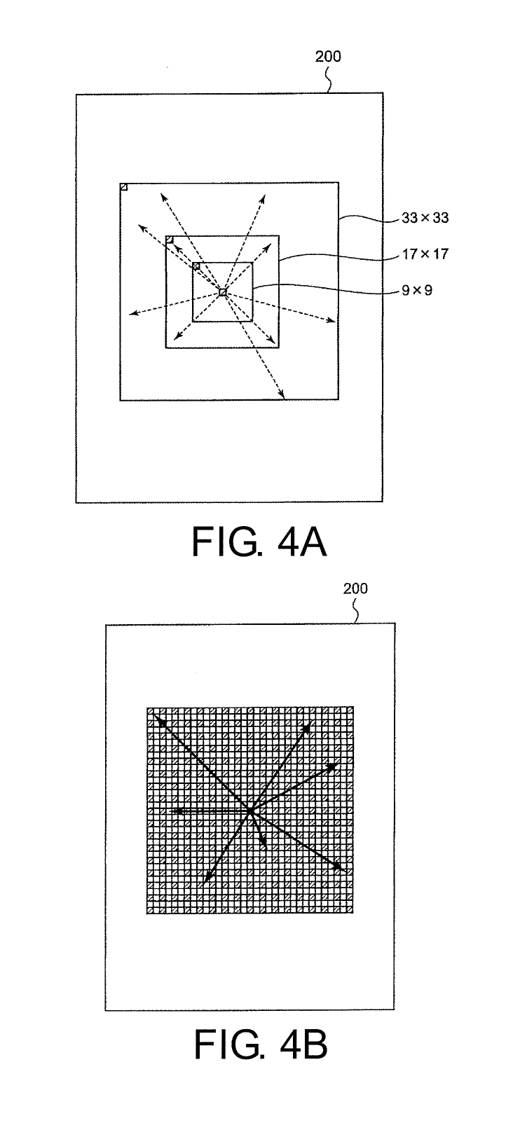

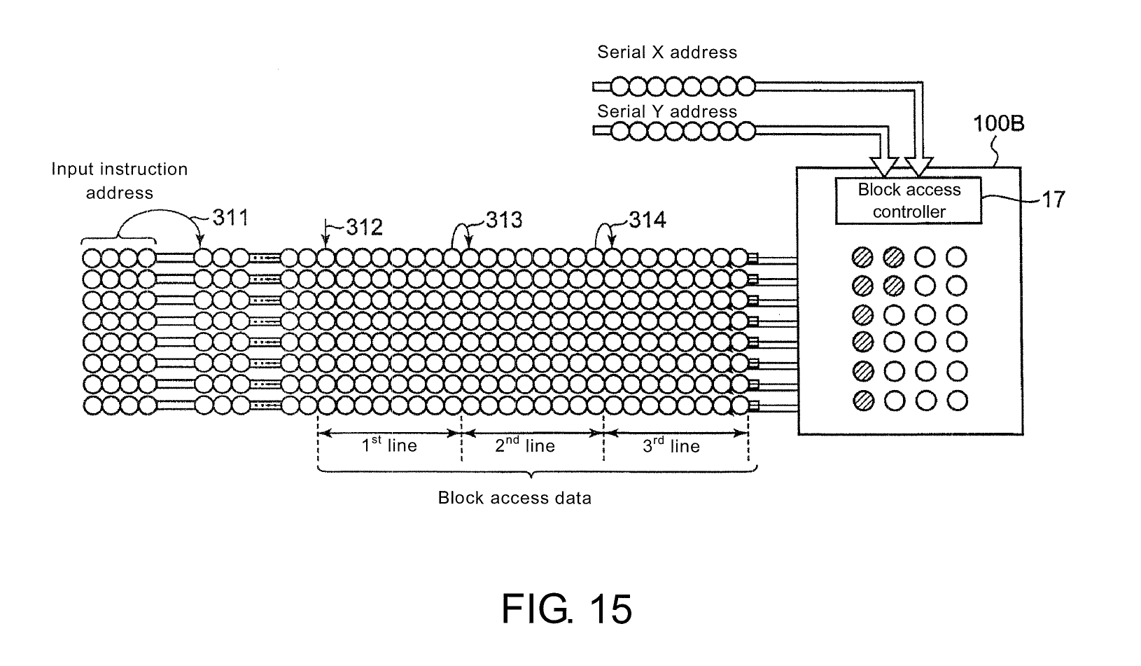

FIG. 15 is a timing diagram of input output time sequence data used for describing a basic operation of the DDR-type DRAM 100B of FIG. 14. In FIG. 15, in access of the first block, data (311 of FIG. 15) is read based on an input instruction address of the address/instruction buffer 3 (instruction is used to set block access (referring to FIG. 3)), and in access of the second block and after, data (312, 313 and 314 of FIG. 15) is read in allusion to each line based on the serial X address and the serial Y address of the serial address buffer 15. Therefore, after the serial address buffer 15 and the block access controller 17 output data in response to the initial address, continuous addresses used for the block addresses are internally generated in the second block through the serial address, so as to output the data obtained from the block address. Moreover, the writing operation is the same.

FIG. 16 is a timing diagram of an operation example of the DDR-type DRAM 100B of FIG. 14, and following signals are indicated in FIG. 16:
(1) CS: chip selection signal;
(2) CK, CK/: clock;
(3) RWDS: read write data strobe signal;
(4) CDX: serial X address enable signal;
(5) AX: serial X address;
(6) CDY: serial Y address enable signal;
(7) AY: serial Y address;
(8) AD/DQa-AD/DQh: address or data of 8 bits (input output through the address/instruction buffer 3 and the data buffer 4).

According to FIG. 16, it is known that in access of the first block, the address is designated by using the address coming from the address/instruction buffer 3, and in access of the second block and after, the address is designated by using the serial address coming from the serial address buffer 15 to output data. In the present embodiment, block access is designated through an input instruction, so as to select pipeline access. In the present embodiment, sufficient operation is implemented in block access of the MPEG application.

### Embodiment 3

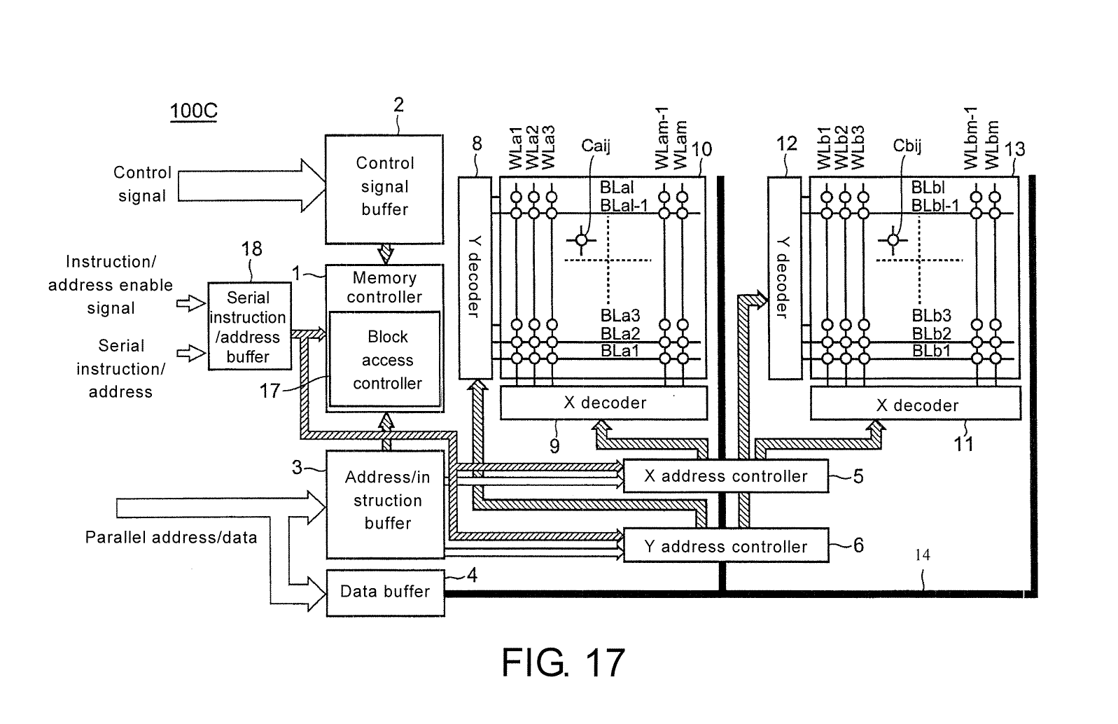

FIG. 17 is a block diagram of a construction example of a DDR-type DRAM 100C of the embodiment 3. In FIG. 17, compared to the DDR-type DRAM 100 of the comparison example of FIG. 9, the DDR-type DRAM 100C of the embodiment 3 has a serial instruction/address buffer 18, and the memory controller 1 has the block access controller 17 similar to that of the embodiment 2.

In FIG. 17, the serial instruction/address buffer 18 inputs and temporarily stores a serial instruction indicating a block size, and access related addresses, etc. of the second block and after, i.e. the serial X address AX, the serial X address enable signal CDX, the serial Y address AY, and the serial Y address enable signal CDY (referring to FIG. 16). The serial instruction, the serial X address enable signal CDX and the serial Y address enable signal CDY are output to the block access controller 17, and the serial X address AX and the serial Y address AY are respectively output to the X address controller 5 and the Y address controller 6. The X address controller 5 and the Y address controller 6 use an address coming from the address/instruction buffer 3 in access of the first block, and use the serial instruction representing a block type and the serial address coming from the serial address buffer 15 to respectively implement block size designation and address designation in access of the second block and after. The block access controller 17 determines the block size of the block access based in the input serial instruction, and performs block access to the designated initial address in the bank interleave manner (as shown in FIG. 1A and FIG. 1B, the bank A and the bank B are alternated) based on the input address and the serial address, so as to perform sequence control for data write, delete and read operations.

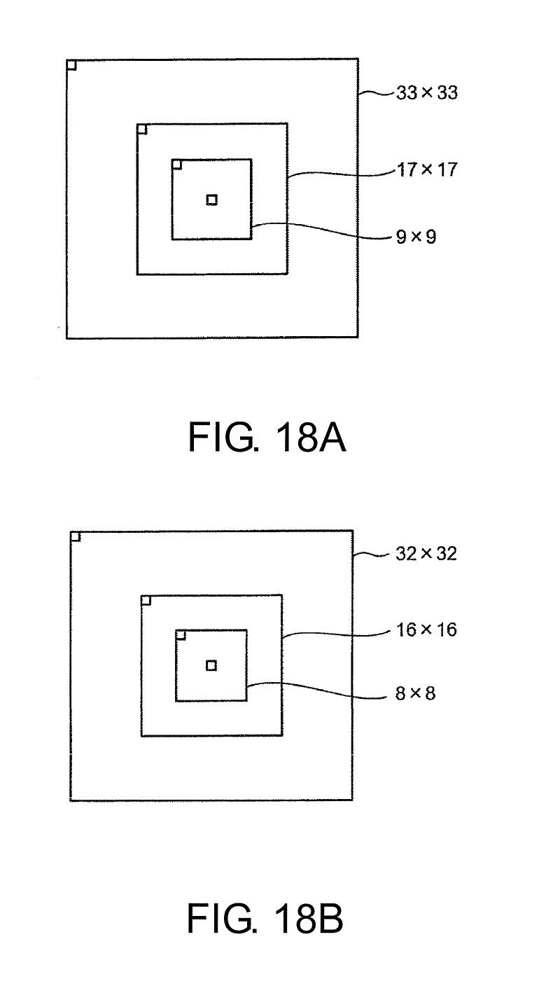

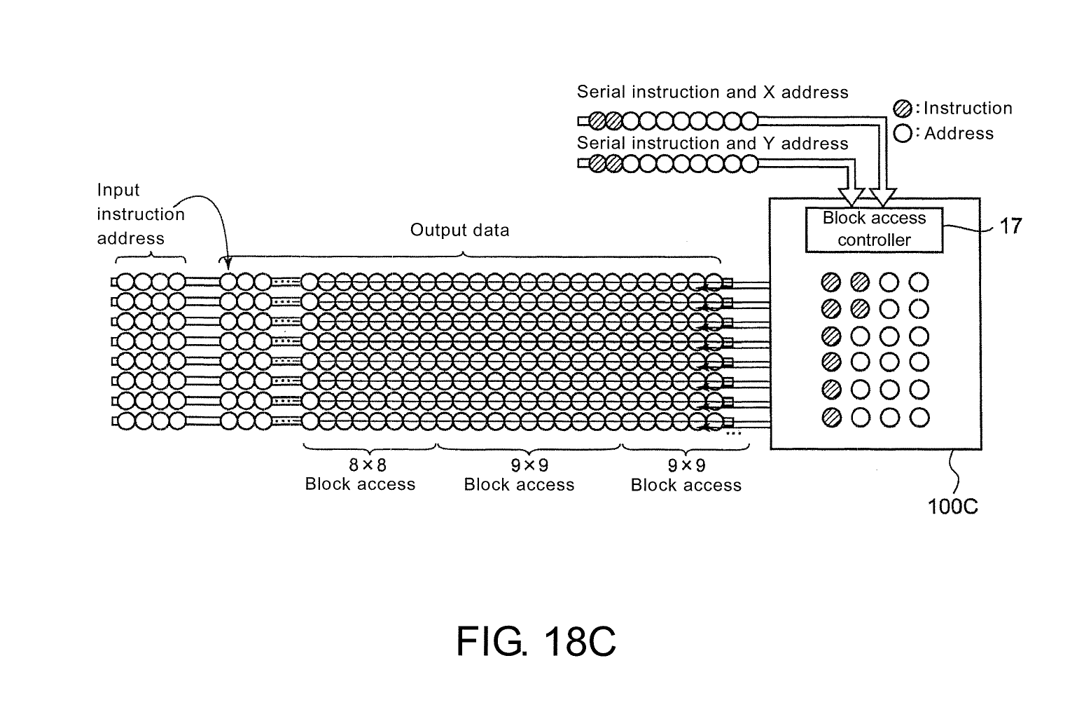

FIG. 18A and FIG. 18B are front views of images of block sizes used in MPEG coding/decoding in the DDR-type DRAM 100C of the embodiment 3. In FIG. 18A, block sizes of 9×9 block, 17×17 block, 33×33 block are illustrated, and in FIG. 18B, block sizes of 8×8 block, 16×16 block, 32×32 block are illustrated.

FIG. 18C is a timing diagram of input output time sequence data used for describing a basic operation of the DDR-type DRAM 100C of FIG. 17. Compared to FIG. 15 of the second embodiment 2, an instruction presenting the block size is appended to the front part of each serial address input to the block access controller 17, such that the block size can be designated to implement selective switch of the block size on the fly. Moreover, when each of the serial addresses is input, block data can be automatically and sequentially accessed subsequently.

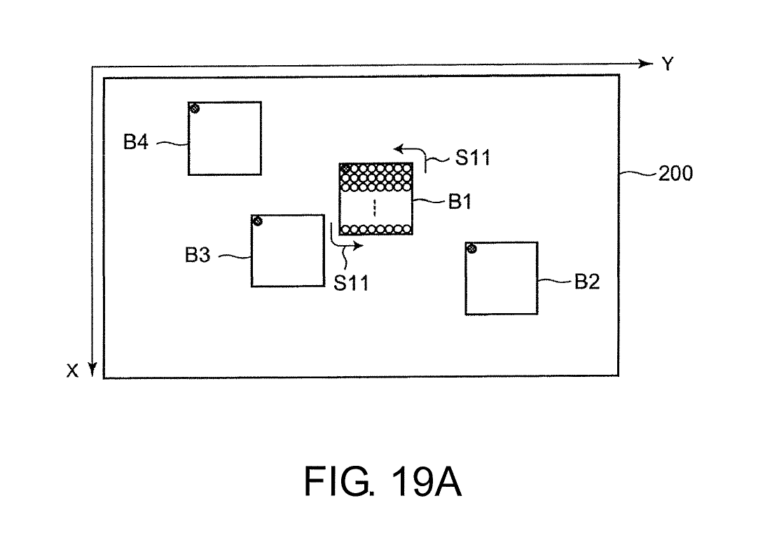

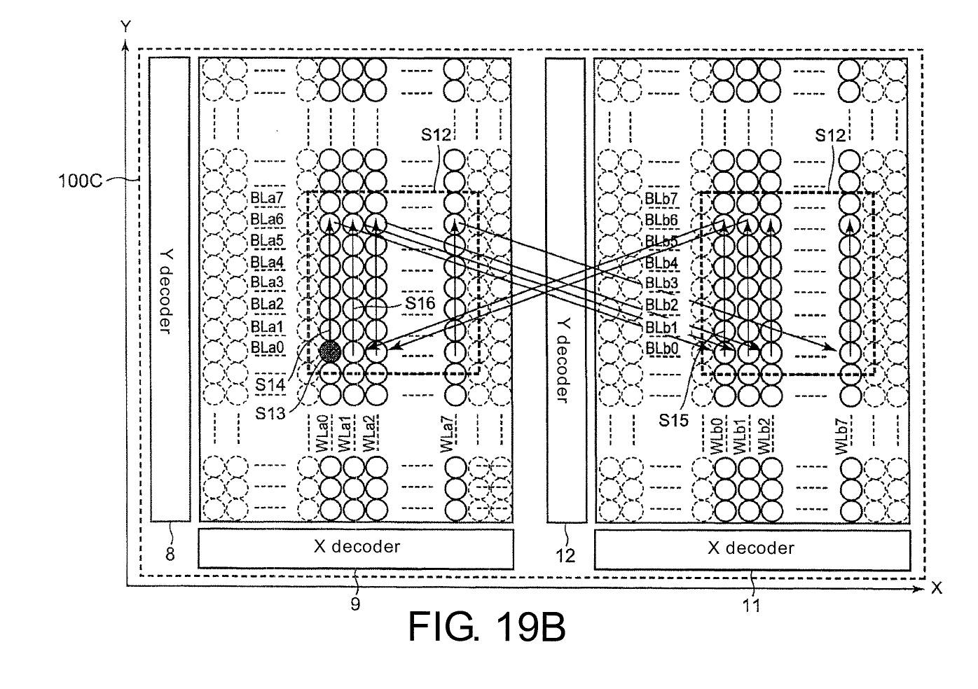

FIG. 19A is a front view of an image of a block access operation of an 8×8 block unit in the DDR-type DARAM 100C of FIG. 17. Moreover, FIG. 19B is a block diagram of a block access operation of an 8×8 block unit in the DDR-type DARAM 100C of FIG. 17. In FIG. 19A, 4 blocks B1-B4 are randomly designated. In FIG. 19B, processing of block access on the image data of the block B1 is automatically performed (step S11-step S16).

(S11) a pixel direction of a video frame corresponds to a Y direction of the memory. A line number direction corresponds to an X direction of the memory. Therefore, allocation of pixel data of the memory array is physically rotated by +90 degrees for easy understanding. In case that the pixels of the video frame are allocated to the memory in the present embodiment, each of the lines of the frame is shown in FIG. 19B, and the lines are divided into odd lines allocated to the bank A and even lines allocated to the bank B.

(S12) then, the initial address used for block access is input. The initial address of the block access is indicated by hatched circles of FIG. 19B. Now, the bank A and the bank B are activated at a same time point, or activation of the bank B is occurred when the bank data is accessed.

(S13) the memory cell selected by the word line WLa0 and the bit line BLa0 is accessed as the initial data of block access.

(S14) the memory cells designated by the bit lines BLa0-BLa7 on the word line WLa0 are respectively accessed.

(S15) after the memory cell designated by the word line WLa0 and the bit line BLa7 is accessed, memory cell access is switched from the bank A to the bank B. Moreover, the memory cells designated by the bit lines BLb0-BLb7 on the word line WLb0 are respectively accessed.

(S16) after the memory cell designated by the word line WLb0 and the bit line BLb7 is accessed, memory cell access is switched from the bank B to the bank A. Moreover, the memory cells designated by the bit line BLa0-BLa7 on the word lines WLa1 are respectively accessed.

(S17) after the steps S14-S16 are repeated, a back pipeline is used to access 8×8 block until the memory cell designated by the bit line BLb7 on the word line WLb7.

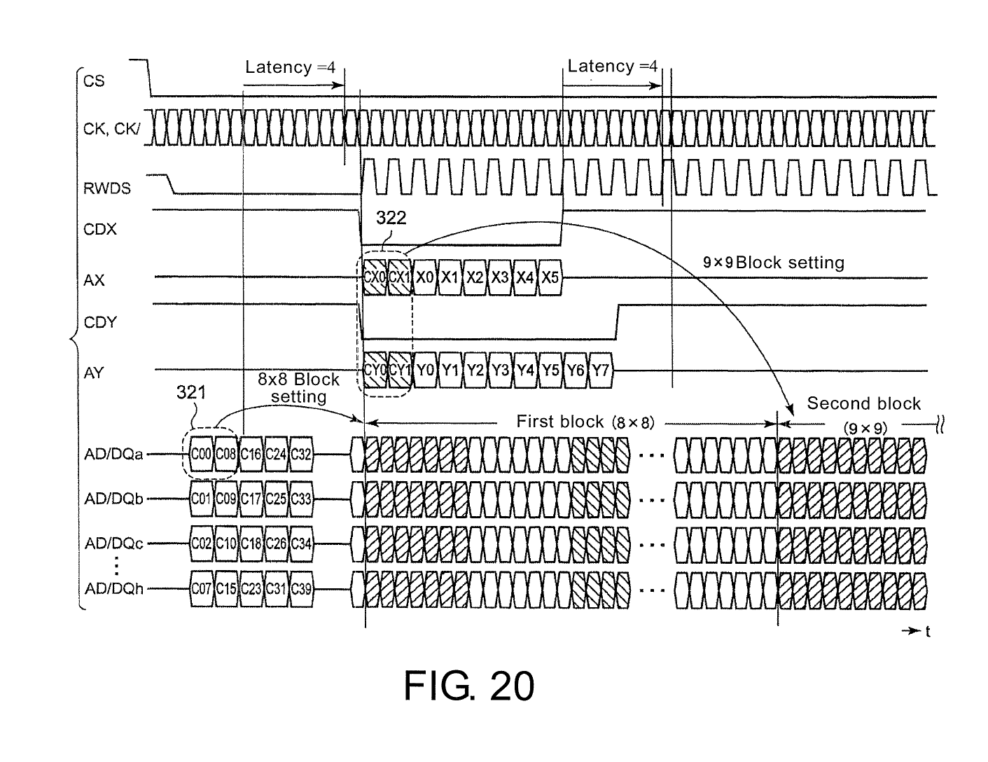

FIG. 20 is a timing diagram of an operation example of the DDR-type DRAM 100C of FIG. 17, and following signals are indicated in FIG. 20:
(1) CS: chip selection signal;
(2) CK, CK/: clock
(3) RWDS: read write data strobe signal;
(4) CDX: serial X address enable signal;
(5) AX: serial X address;
(6) CDY: serial Y address enable signal;
(7) AY: serial Y address;
(8) AD/DQa-AD/DQh: address or data of 8 bits (input output through the address/instruction buffer 3 and the data buffer 4).

According to FIG. 20, it is known that in access of the first block, the address is designated by an instruction 321 designated by a previous block size of the address coming from the address/instruction buffer 3 and is applied for accessing the 1^{st} block, and in access of the second block and after, the address is designated by an instruction 322 designated by a previous block size of the serial X address and the serial Y address coming from the address/instruction buffer 3 and is applied for accessing the 2^{nd} block. In the present embodiment, besides the serial address, block access can be designated through an instruction designated by the input block size, so as to implement pipeline access. In the present embodiment, sufficient operation is implemented in block access of the MPEG application.

### Embodiment Effects

The aforementioned embodiments have following effects:
(1) Since the semiconductor chip of 24 balls with the less number of pins compared to that of 78 balls or 96 balls is used, the chip cost and system cost of the semiconductor chip is lower than that of the semiconductor chip with general number of pins.
(2) The high resolution MPEG application cannot be used in the DDR-type DRAM with less number of pins of the existing example, in the embodiment 1 to the embodiment 3, by using the serial address buffer 15 or the serial instruction/address buffer 18 and the bank interleave column access controller 16 or the block access controller 17, a less number of pins can be used to write or read the image data of the MPEG application to/from the DDR-type DRAM.

Differences between the invention and the patent literatures 1-9:

The patent literatures 1-4, the patent literature 6, the patent literature 7, the patent literature 9 disclose pipeline processing of band interleave, the patent literatures 5-7 and the patent literature 9 disclose bank access control, and the patent literature 6-8 disclose control of accessed bit number without disclosing or implying the following features of the embodiments: the serial address buffer 15 or the serial instruction/address buffer 18 and the bank interleave column access controller 16 or the block access controller 17.

The DRAM is described in the aforementioned embodiments, though the invention is not limited thereto, and the concept of the invention can be applied to various semiconductor memory devices capable of implementing bank switch.

In the aforementioned embodiments, in the DDR-type DRAM, the bank A and the bank B are selectively switched to implement a data write or read operation, though the invention is not limited thereto, and three or more banks can be selectively switched to implement the data write or read operation.

### INDUSTRIAL APPLICABILITY

As described above, according to the semiconductor memory device and the address control method thereof of the invention, image data of a wider frequency band compared to that of the existing technique such as the MPEG data, etc., can be written into or read from the semiconductor memory device with less number of pins.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A semiconductor memory device, selectively switching at least two banks based on an input parallel address for writing or reading data, the semiconductor memory device comprising:
a control unit, controlled according to a following method: in a first data access, accessing the semiconductor memory device according to the input parallel address; and then in a second data access and after, accessing the semiconductor memory device according to a serial address different to the parallel address.

2. The semiconductor memory device as claimed in claim 1, wherein
the semiconductor memory device is constructed by respectively connecting memory cells to intersections of a plurality of word lines and a plurality of bit lines,
the serial address contains: a 1^{st} serial address for selecting one word line in the plurality of word lines, and a 2^{nd} serial address for selecting one bit line in the plurality of bit lines.

3. The semiconductor memory device as claimed in claim 2, wherein the 1St serial address and the 2^{nd} serial address are serially input to the semiconductor memory device.

4. The semiconductor memory device as claimed in claim 1, wherein
the semiconductor memory device is a semiconductor memory device writing or reading data in block unit,
the control unit is controlled according to a following method: in a first block access, accessing the semiconductor memory device according to the input parallel address; and then in a second block access and after, accessing the semiconductor memory device according to the serial address different to the parallel address.

5. The semiconductor memory device as claimed in claim 4, wherein the control unit changes a block size for writing or reading data based on a serial instruction input in a front part of the serial address and representing the block size.

6. An address control method of a semiconductor memory device, selectively switching at least two banks based on an input parallel address for writing or reading data, the address control method of the semiconductor memory device comprising:
a control step, implementing control according to a following method: in a first data access, accessing the semiconductor memory device according to the input parallel address; and then in a second data access and after, accessing the semiconductor memory device according to a serial address different to the parallel address.

7. The address control method of the semiconductor memory device as claimed in claim 6, wherein
the semiconductor memory device is constructed by respectively connecting memory cells to intersections of a plurality of word lines and a plurality of bit lines, the serial address contains: a 1^{st} serial address for selecting one word line in the plurality of word lines, and a 2^{nd} serial address for selecting one bit line in the plurality of bit lines.

8. The address control method of the semiconductor memory device as claimed in claim 7, wherein the 1^{st} serial address and the 2^{nd} serial address are serially input to the semiconductor memory device.

9. The address control method of the semiconductor memory device as claimed in claim 6, wherein
the semiconductor memory device is a semiconductor memory device writing or reading data in block unit,
the control step implements control according to a following method: in a first block access, accessing the semiconductor memory device according to the input parallel address; and then in a second block access and after, accessing the semiconductor memory device according to the serial address different to the parallel address.

10. The address control method of the semiconductor memory device as claimed in claim 9, wherein in the control step, changing a block size for writing or reading data based on a serial instruction input in a front part of the serial address and representing the block size.
